(19) United States
(12) Patent Application Publication
(10) Pub. No.: US 2011/0241644 A1
(43) Pub. Date: Oct. 6, 2011

(54) SEMICONDUCTOR DEVICE AND METHOD OF MANUFACTURING THE SAME AND POWER SUPPLY DEVICE

(75) Inventors: Takayuki HASHIMOTO, Tokai (JP); Masahiro MASUNAGA, Hitachi (JP)

(73) Assignee: RENESAS ELECTRONICS CORPORATION, Kanagawa (JP)

(21) Appl. No.: 13/074,138

(22) Filed: Mar. 29, 2011

(30) Foreign Application Priority Data
Mar. 30, 2010 (JP) 2010-77033
Aug. 27, 2010 (JP) 2010-190557

(51) Int. Cl. G05F 5/00; H01L 29/78; H01L 21/336

(52) U.S. Cl. 323/299; 257/329; 438/268; 257/E29.262; 257/E21.41

(57) ABSTRACT

Technology of reducing leakage current in a planar MOSFET and a hollow gate type planar MOSFET is provided. In a planar MOSFET (and hollow gate type planar MOSFET), regions close to a channel in n-type source regions have a shallow depth (shallow n-type source region), and regions away from the channel have a large depth (deep n-type source region). Protruding portions in a horizontal direction of p-type well regions are positioned further inside than a surface of a substrate. In this manner, a planar MOSFET (and a hollow gate type planar MOSFET) having small leakage current can be achieved, and thus there is an effect in loss reduction in a power source using the planar MOSFET (and the hollow gate type planar MOSFET).

### CROSS-REFERENCE TO RELATED APPLICATIONS

The present application claims priorities from Japanese Patent Application No. 2010-77033 filed on Mar. 30, 2010, and Patent Application No. 2010-190557 filed on Aug. 27, 2010, the contents of which are hereby incorporated by reference into this application.

### BACKGROUND

The present invention relates to a semiconductor device for power conversion, and more particularly relates to technology effectively applied to a power MOSFET and a power supply device using the power MOSFET.

Trench MOSFET (metal oxide semiconductor field effect transistor) has been used in switching power supply (hereinafter, VR: voltage regulator) which supplies power to CPUs (central processor units) in personal computers and servers (e.g., Japanese Patent Application Laid-Open Publication No. 2008-218711 (Patent Document 1) and Japanese Patent Application Laid-Open Publication No. 2005-57050 (Patent Document 2)). The trench MOSFET has a smaller cell pitch than planar MOSFETs (e.g., J. Ng et al., “A Novel Planar Power MOSFET With Laterally Uniform Body and Ion-Implanted JFET Region,” IEEE Electron Device Letter, 2008, vol. 29, no. 4, pp. 375-377, April. 2008 (Non-Patent Document 1)) and thus has advantages in a large channel width per unit area and being capable of reducing on-resistance, but has a disadvantage in a large feedback capacitance as having a large facing area of a trench gate and a drain region.

In recent years, to achieve larger current and lower voltage in CPUs, the number of output capacitors, which suppress fluctuations of CPU voltage occurring when power consumption of the CPU is changed, has been increased, resulting in an increase in the size of VR and cost. To reduce the number of the output capacitors, it has been known that increasing the switching frequency of the VR is effective (e.g., Y. Ren et al., “Analysis of the Power Delivery Path from the 12-V VR to the Microprocessor,” Proc. IEEE APEC '04, 2004 vol. 1, pp. 285-291 (Non-Patent Document 2) and M. Xu et al., “Small Signal Modeling of a High Bandwidth Voltage Regulator Using Coupled Inductor,” IEEE Trans. Power Electronics, Vol. 22, No. 2, pp. 399-406, March 2007 (Non-Patent Document 3)).

A bottleneck in improving switching frequency is that temperature of MOSFETs exceeds the upper limit of operating temperature (e.g., 150° C.) due to loss generated along with switching. As the loss generated upon switching, there are turn-on loss, turn-off loss, and drive loss regarding a high-side MOSFET of VR, and there are conduction loss and recovery loss of an embedded diode and drive loss related to a low-side MOSFET. Among these types of loss, the turn-on loss and turn-off loss of the high-side MOSFET have large rates in comparison. Hereinafter, the turn-on loss and turn-off loss will be collectively called “switching loss.”

To reduce the switching loss, reducing the feedback capacitance of the MOSFET is effective. The reason is, when the feedback capacitance is reduced, the speed of switching is increased and so the switching loss is reduced. The trench MOSFET originally has a problem of large feedback capacitance, and so there is a difficulty in further improving the switching frequency.

When the switching frequency of VR is low (about 300 kHz), the ratio of the conduction loss occupying the loss of VR is high, and thus the trench MOSFET having a low on-resistance is advantageous. Meanwhile, when the switching frequency is high (higher than 1 MHz), the switching loss is dominant, and thus the planar type MOSFET having a small feedback capacitance is advantageous. As a structure capable of further reducing the feedback capacitance of the planar MOSFET, a structure in which a center portion of a gate electrode of a planar MOSFET is eliminated (hereinafter, called “hollow gate type planar MOSFET”) has been suggested (e.g., H. Esaki et al., “A 900 MHz 100 W VD-MOSFET WITH SILICIDE GATE SELF-ALIGNED CHANNEL,” Proc. IEEE IEDM '04, 1984, pp. 447-450 (Non-Patent Document 4)). The hollow gate type planar MOSFET has a smaller overlap of a gate electrode and a drain region as compared to the planar MOSFET, and thus the feedback capacitance can be significantly reduced.

### SUMMARY

The inventors of the present invention have found out that the hollow gate type planar MOSFET has a problem of increasing leakage current due to depletion layers penetrating into a channel in an off state.

Accordingly, the present invention has been made to solve the problem in the above-mentioned existing technologies, and a typical preferred aim of the present invention is to provide technology of reducing leakage current in a planar MOSFET and a hollow gate type planar MOSFET. Note that, while the present invention has been made in a process of researching and developing a hollow gate type planar MOSFET, the present invention is effective in reducing leakage current also in the existing planar MOSFET. Therefore, in the present specification, embodiments using the present invention will be described regarding both the planar MOSFET and the hollow gate type planar MOSFET.

The above and other preferred aims and novel characteristics of the present invention will be apparent from the description of the present specification and the accompanying drawings.

The typical ones of the inventions disclosed in the present application will be briefly described as follows.

More specifically, a brief description of a typical embodiment is that source regions of a planar MOSFET and a hollow gate type planar MOSFET include shallow source regions in contact with a gate insulator and deep source regions being away from the gate insulator. More specifically, regions in n-type source regions close to a channel are shallow and regions away from the channel are deep. Further, as to well regions, protruding portions in a horizontal direction in p-type well regions are positioned further inside than a substrate surface.

The effects gained by typical aspects of the present invention will be briefly described below.

More specifically, an effect gained by typical aspects of the present invention is to achieve a planar MOSFET and a hollow gate type planar MOSFET having small leakage current and a loss reduction in a power supply device using the planar MOSFET and hollow gate type planar MOSFET.

### BRIEF DESCRIPTION OF THE DRAWINGS

FIG. 1 is a cross-sectional view illustrating a planar MOSFET which is a semiconductor device according to a first embodiment of the present invention;

FIG. 2 is a cross-sectional view illustrating a planar MOSFET which is a semiconductor device according to a second embodiment of the present invention;

FIG. 3 is a cross-sectional view illustrating a planar MOSFET which is a semiconductor device according to a third embodiment of the present invention;

FIG. 4 is a cross-sectional view illustrating a hollow gate type planar MOSFET which is a semiconductor device according to a fourth embodiment of the present invention;

FIG. 5 is a cross-sectional view illustrating a hollow gate type planar MOSFET which is a semiconductor device according to a fifth embodiment of the present invention;

FIG. 6 is a cross-sectional view illustrating a hollow gate type planar MOSFET which is a semiconductor device according to a sixth embodiment of the present invention;

FIG. 7 is a diagram describing extensions of depletion layers in an off state according to the sixth embodiment of the present invention;

FIG. 8 is a cross-sectional view illustrating a hollow gate type planar MOSFET which is a semiconductor device according to a seventh embodiment of the present invention;

FIG. 9 is a cross-sectional view illustrating a hollow gate type planar MOSFET which is a semiconductor device according to an eighth embodiment of the present invention;

FIG. 10 is a cross-sectional view illustrating a hollow gate type planar MOSFET which is a semiconductor device according to a ninth embodiment of the present invention;

FIG. 11 is a circuit diagram illustrating a power MOSFET to which a snubber resistor and a snubber capacitor are added according to the ninth embodiment of the present invention;

FIG. 12 is a circuit diagram illustrating a non-insulted Buck converter which is a power supply device according to the ninth embodiment of the present invention;

FIG. 13 is a diagram illustrating a voltage waveform upon switching according to the ninth embodiment of the present invention;

FIG. 14 is a cross-sectional view describing a manufacturing process of a method of manufacturing a hollow gate type planar MOSFET using the hollow gate type planar MOSFET of the sixth embodiment of the present invention as an example;

FIG. 15 is a cross-sectional view describing the manufacturing process continued from FIG. 14;

FIG. 16 is a cross-sectional view describing the manufacturing process continued from FIG. 15;

FIG. 17 is a cross-sectional view describing the manufacturing process continued from FIG. 16;

FIG. 18 is a cross-sectional view describing the manufacturing process continued from FIG. 17; and

FIG. 19 is a cross-sectional view describing the manufacturing process continued from FIG. 18.

### DETAILED DESCRIPTION

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

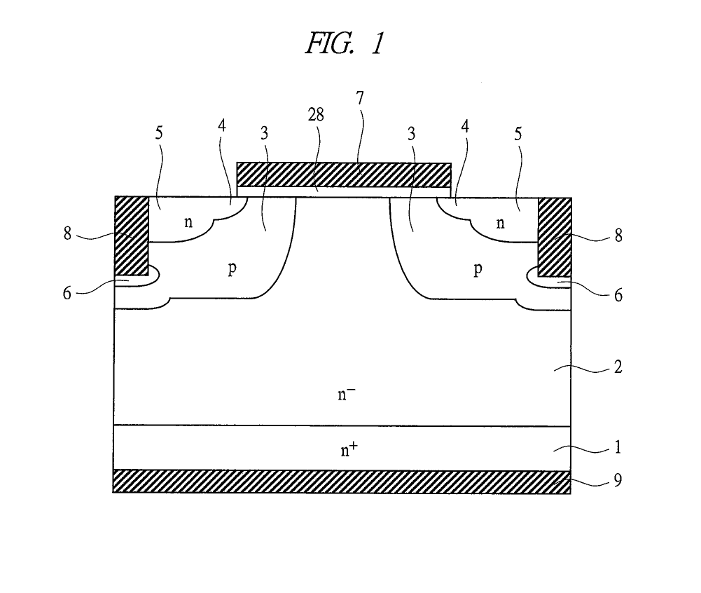

FIG. 1 illustrates a cross-sectional view of a planar MOSFET which is a semiconductor device according to a first embodiment of the present invention. 1 denotes an n⁺-type substrate, 2 denotes an n⁻-type layer, 3 denotes a p-type well region, 4 denotes a shallow n-type source region, 5 denotes a deep n-type source region, 6 denotes a p⁺-type contact region, 7 denotes a gate electrode, 8 denotes a source electrode, 9 denotes a drain electrode, and 28 denotes a gate insulator. Regarding the symbol “+” or “−” after “n” or “p,” “+” means that an impurity concentration is high, and “−” means that an impurity concentration is low.

In the planar MOSFET of the present embodiment, the drain electrode 9 is formed on a back surface of the n⁺-type substrate 1 which is a semiconductor substrate. A plurality of the p-type well regions 3 are formed on a surface of the n⁺-type substrate 1. The n⁻-type layer 2 which is a first semiconductor region is formed on the surface of the n⁺-type substrate 1, and has a conductivity opposite to that of the p-type well region 3. A plurality of the shallow n-type source regions 4 and the deep n-type source regions 5 are formed in the p-type well region 3. The gate insulator 28 is formed on the p-type well region 3 and the n⁻-type layer 2. The gate electrode 7 is formed on the gate insulator 28. The source electrodes 8 are electrically connected to the shallow n-type source regions 4 and the deep n-type source regions 5.

In this planar MOSFET, when positive voltage is applied to the gate electrode 7, a surface (channel) of the p-type well region 3 under the gate insulator 28 is turned to n-type, so that current flows from the drain electrode 9 to the source electrode 8.

A different point of the planar MOSFET of the present embodiment from the existing planar MOSFET is that the source region is formed of the shallow n-type source region 4 and the deep n-type source region 5, where the n-type source region 4 close to the channel is shallow and the n-type source region 5 away from the channel is deep. In other words, the shallow n-type source region 4 is a source region being in contact with the gate insulator 28, and the deep n-type source region 5 is a source region being away from the gate insulator 28. In the present specification, this structure will be called “two-step source structure.”

For example, when the source regions are formed of only the shallow n-type source regions 4, as diffusion of the n-type source regions 4 in the horizontal direction is small, a distance (channel length) of the p-type well region 3 at the surface is long, and thus penetration of the depletion layers in the off state is suppressed and leakage current is reduced. However, a resistance (source resistance) in the horizontal direction of the shallow n-type source regions is large, and thus there is a problem of an increase in on resistance. Meanwhile, when the source region is formed of only the deep n-type source region 5, while the source resistance is small, as diffusion of the n-type source region in the horizontal direction is large, the channel length is shortened, and thus the leakage current is increased. On the contrary, the two-step structure of the present embodiment has both the features of the shallow source region 4 and the deep source region 5, and thus leakage current and source resistance are small.

### Second Embodiment

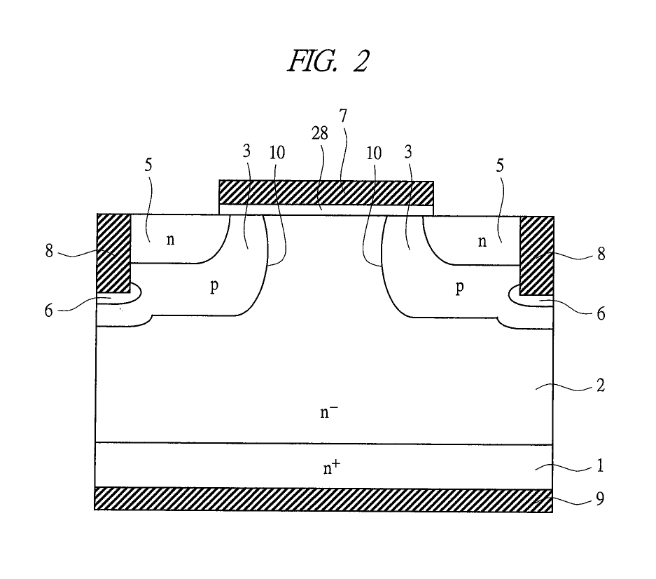

FIG. 2 illustrates a cross-sectional view of a planar MOSFET which is a semiconductor device according to a second embodiment of the present invention. The planar MOSFET of the present embodiment is a different example from the first embodiment. 1 denotes an n⁺-type substrate, 2 denotes an n⁻-type layer, 3 denotes a p-type well region, 5 denotes a deep n-type source region, 6 denotes a p⁺-type contact region, 7 denotes a gate electrode, 8 denotes a source electrode, 9 denotes a drain electrode, and 28 denotes a gate insulator.

A different point of the planar MOSFET of the present embodiment from the existing planar MOSFET is protruding portions 10 in a horizontal direction of the p-type well regions 3 being positioned further inside than a substrate surface. In other words, top portions of the protrusions in the horizontal direction of the p-type well regions 3 are positioned further inside (on the n⁺-type substrate 1 side) than boundary faces of the p-type well regions 3 and the gate insulator 28. As the protruding portions 10 are positioned further inside than the substrate surface, it is easier for the depletion layers extending from the p-type well regions 3 to the n⁻-type layer 2 in an off state to be in contact with (pinched-off) each other (=depletion layers extending from the p-type wells 3 are in contact with each other at low drain voltage) and thus penetration of the depletion layers to the channel is suppressed.

### Third Embodiment

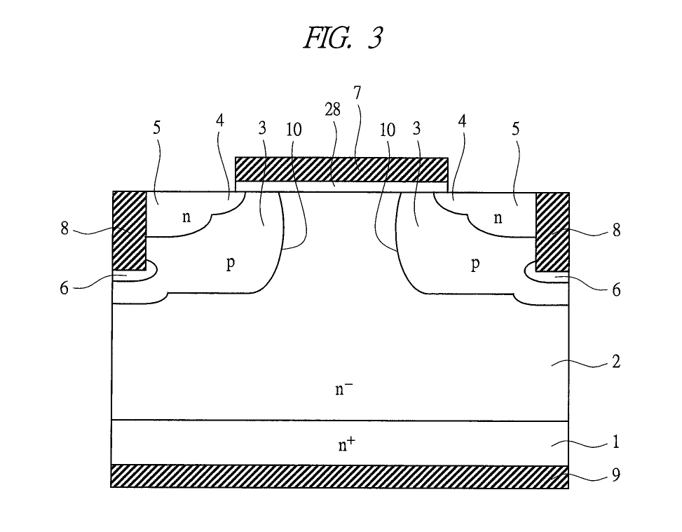

FIG. 3 illustrates a cross-sectional view of a planar MOSFET which is a semiconductor device according to a third embodiment of the present embodiment. The planar MOSFET of the present embodiment has features of both the first embodiment and the second embodiment. That is, source regions are formed of the shallow n-type source regions 4 and the deep n-type source regions 5, where the n-type source regions 4 close to the channel are shallow and the n-type source region 5 away from the channel are deep. Further, the protruding portions 10 in the horizontal direction of the p-type well regions 3 are positioned further inside than the substrate surface. As described later, by implementing the first embodiment and the second embodiment at the same time, a synergistic effect is gained as compared with the case of implementing them independently.

### Fourth Embodiment

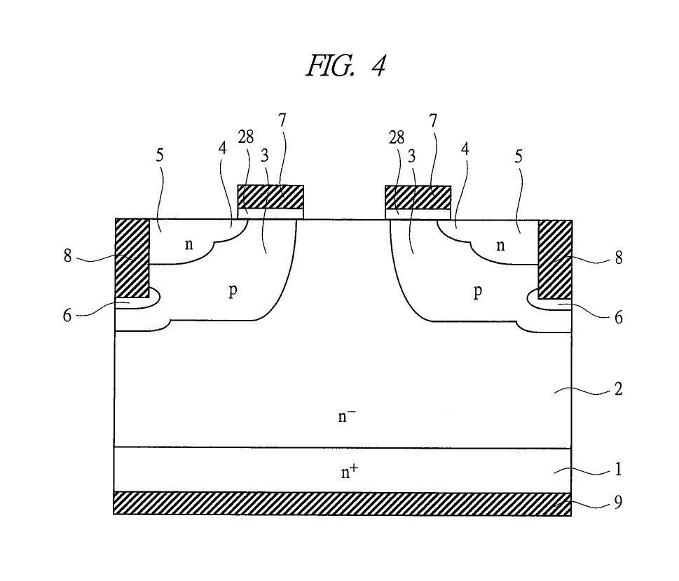

FIG. 4 illustrates a cross-sectional view of a hollow gate type planar MOSFET which is a semiconductor device according to a fourth embodiment of the present invention. A different point of the hollow gate type planar MOSFET of the present embodiment from the first embodiment is that a center portion of the gate electrode 7 is eliminated to have an opening portion. In the hollow gate type planar MOSFET, it is difficult for the depletion layers to be in contact (pinched-off) with each other in an off state as compared to the existing planar MOSFET, and thus an increase in leakage current due to penetration of the depletion layers is significant. While the two-step structure does not increase the source resistance even in the existing planar MOSFET and thus has an effect of suppressing leakage current, the two-step structure is more effective in the hollow gate type planar MOSFET having the problem of leakage current.

### Fifth Embodiment

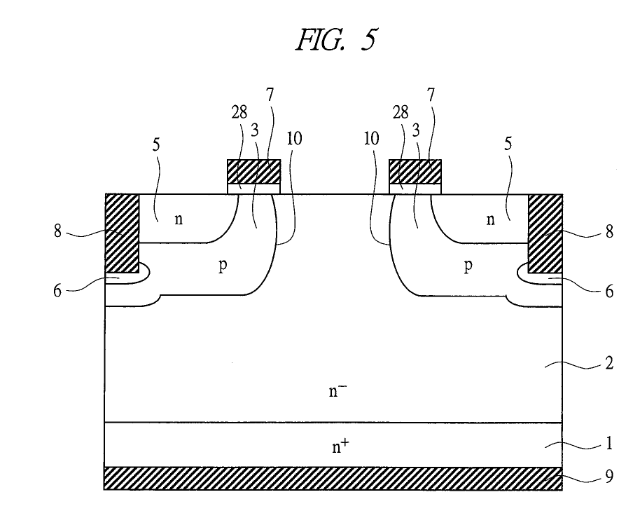

FIG. 5 illustrates a cross-sectional view of a hollow gate type planar MOSFET which is a semiconductor device of a fifth embodiment of the present invention. A different point of the hollow gate type planar MOSFET of the present embodiment from the second embodiment is that a center portion of the gate electrode 7 is eliminated to have an opening portion. In the hollow gate type planar MOSFET, it is difficult for the depletion layers to be in contact (pinched-off) with each other in an off state as compared to the existing planar MOSFET, and thus an increase in leakage current due to penetration of the depletion layers is significant. In the structure in which the protruding portions 10 in the p-type well region are positioned further inside than the substrate surface, since it is easy for the depletion layers to be pinched-off (=depletion layers extending from the p-type well regions 3 are in contact with each other at low voltage) even in the existing planar MOSFET, there is an effect of suppressing leakage current and thus the structure is more effective in the hollow gate type planar MOSFET having a more severe problem of leakage current.

### Sixth Embodiment

FIG. 6 illustrates a cross-sectional view of a hollow gate type planar MOSFET which is a semiconductor device according to a sixth embodiment of the present invention. A different point of the hollow gate type planar MOSFET of the present embodiment from the third embodiment is that a center portion of the gate electrode 7 is eliminated to have an opening portion. In the hollow gate type planar MOSFET, it is difficult for the depletion layers to be in contact (pinched-off) with each other in an off state as compared to existing planar MOSFET, and thus an increase in leakage current due to penetration of the depletion layers is significant. In the structure having the two-step structure and also having the protruding portions 10 in the horizontal direction of the p-type wells 3 being positioned further inside than the substrate surface, since it is easy for the depletion layers to be pinched-off (=depletion layers extending from the p-type well regions 3 are in contact with each other at low voltage) even in the existing planar MOSFET, there is an effect of suppressing leakage current and thus the structure is more effective in the hollow gate type planar MOSFET having a more severe problem of leakage current.

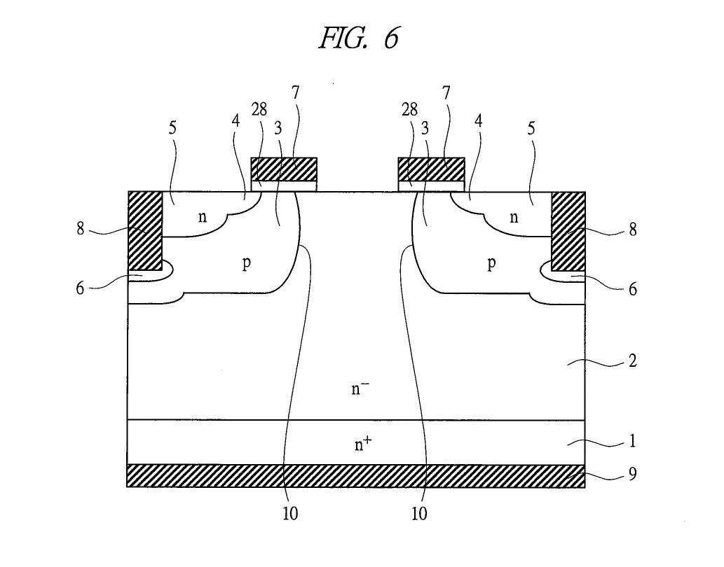

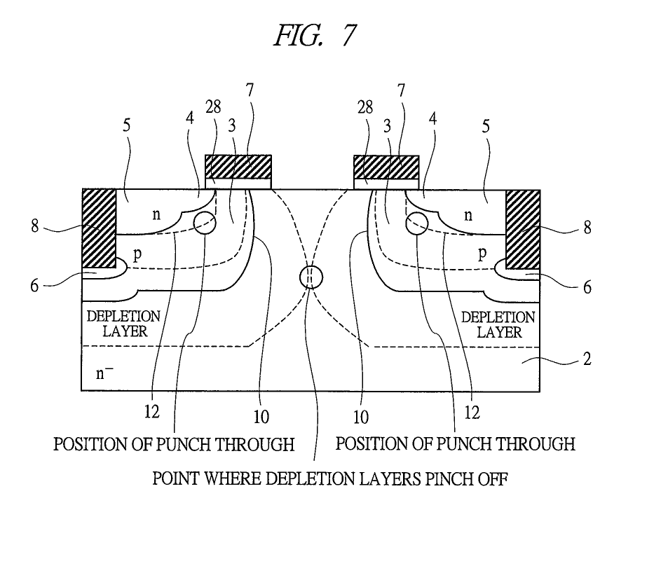

Next, with reference to FIG. 7, gaining a synergetic effect when using both the “two-step structure” and the “structure in which the protruding portions 10 in the horizontal direction of the p-type wells 3 are positioned further inside than the substrate surface” more than when using the structures independently will be explained. FIG. 7 is a cross-sectional view of the sixth embodiment in an off state, in which the dotted lines 12 indicate boundaries of pn junctions in one-step structures having deep n-type source regions. Since the protruding portions 10 in the horizontal direction are positioned further inside than the substrate surface, the depletion layers extending from the p-type well regions 3 to the n⁻-type layer 2 are in contact (pinched-off) with each other inside the substrate. Therefore, the electrical field of the channel is mitigated, shortening the distance for which the depletion layers penetrate. As the depletion layers extending in the p-type well regions 3 are longer on the bottom sides of the p-type well regions 3 as compared to the channel, the depletion layers from the p-type well region 3 are in contact with (punch through) the n-type source regions (the boundaries 12 of the pn junctions in the one-step structures having deep n-type source regions) at corner portions. Thus, by making the corner portions in the n-type source regions shallow, an increase of source resistance can be suppressed to the minimum, and punch through (=increase in leakage current) can be suppressed.

### Seventh Embodiment

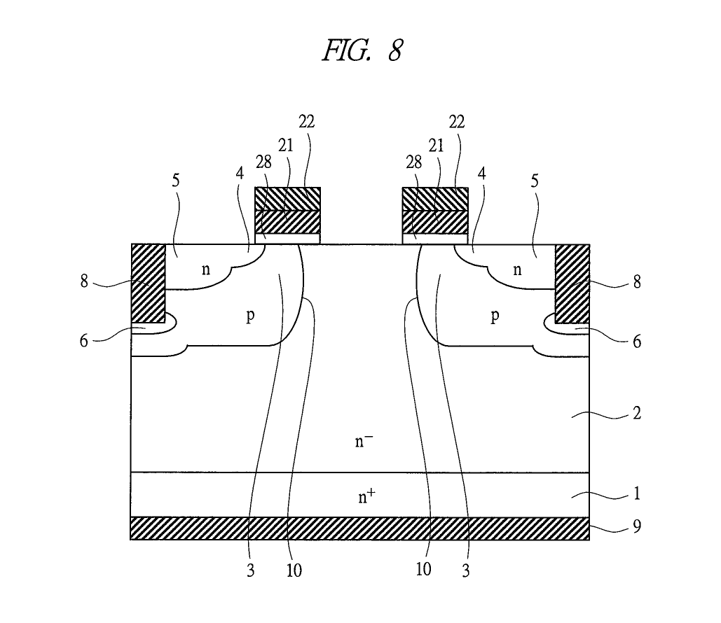

FIG. 8 illustrates a cross-sectional view of a hollow gate type planar MOSFET which is a semiconductor device according to a seventh embodiment of the present invention. A different point of the hollow gate type planar MOSFET of the present embodiment from the sixth embodiment is that the gate electrode 7 is formed of a stacked-layer film having a two-layer structure of polysilicon 21 and silicide 22. Since a cross-section area of the gate electrode 7 is small in the hollow gate type planar MOSFET, there has been a problem of an increase in gate resistance. By using the two-layer structure of the polysilicon 21 and silicide 22 to the gate electrode 7, the gate resistance can be reduced by 10 times as compared to the one-layer structure of polysilicon.

### Eighth Embodiment

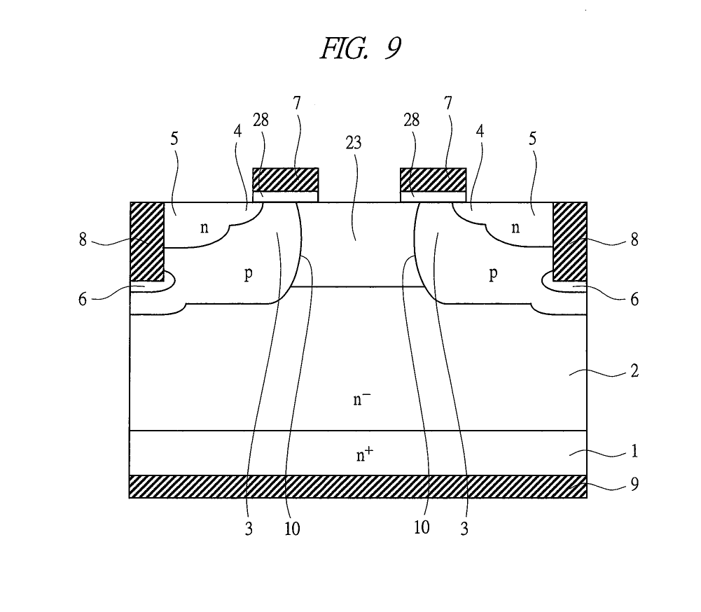

FIG. 9 illustrates a hollow gate type planar MOSFET according to an eighth embodiment of the present invention. A different point of the hollow gate type planar MOSFET of the present embodiment from the sixth embodiment is that an n-type region 23 having a conductivity opposite to that of the p-type well regions 3 and having a higher impurity concentration (lower resistance) than the n⁻-type layer 2 is provided between the p-type well regions 3. When providing the n-type region 23 without using the “two-step structure” and the “structure in which the protruding portions 10 in the horizontal direction of the p-type well regions 3 are positioned further inside than the substrate surface,” there has been a problem of an increase in leakage current because it is difficult for the depletion layers to extend from the p-type well regions 3 to the n-type region 23. By using the “two-step structure” and the “structure in which the protruding portions 10 in the horizontal direction of the p-type well regions 3 are positioned further inside than the substrate surface,” a margin to leakage current is increased, and thus it is possible to reduce the on-resistance by providing the n-type region 23 to lower the resistance (JFET resistance) between the p-type well regions 3.

### Ninth Embodiment

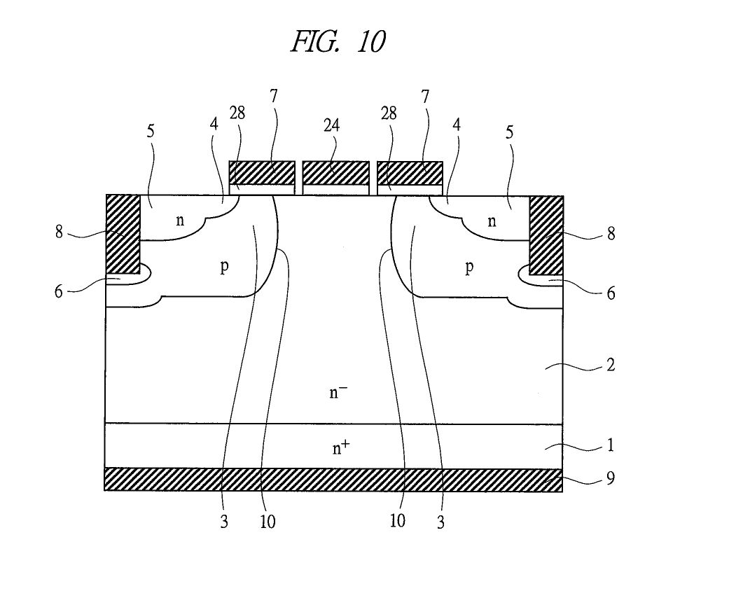

FIG. 10 illustrates a cross-sectional view of a hollow gate type planar MOSFET which is a semiconductor device according to a ninth embodiment of the present invention. A different point of the hollow gate type planar MOSFET of the present embodiment from the sixth embodiment is that a dummy gate electrode 24 at a source potential is provided to the opening portion of the gate electrode 7. The dummy gate electrode 24 is separated from the gate electrode 7, and formed on the gate insulator 28 formed just above the n⁻-type layer 2, and electrically connected to the source electrode 8. The dummy gate electrode 24 has a function of easing extension of the depletion layers extending from the p-type well regions 3 to the n⁻-type layer 2 (RESURF effect) and thus leakage current is reduced.

The inventors of the present invention have found out that it is possible to suppress voltage fluctuation upon switching by optimizing the resistance value of the dummy gate electrode 24, and this will be described hereinafter with reference to FIGS. 11 to 13.

FIG. 11 is a circuit diagram in which a snubber resistor 43 and a snubber capacitor 44 are added to a power MOSFET 41 and a body diode 42. The series circuit of the snubber resistor 43 and the snubber capacitor 44 is connected between drain and source of the power MOSFET 41 to have an effect of suppressing voltage fluctuation upon switching of the power MOSFET 41. Since a parasitic capacitance between the dummy gate 24 and the n⁻-type layer 2 in FIG. 10 corresponds to the snubber resistor 43, the structure in FIG. 10 embeds a snubber circuit. When the resistance of the dummy gate electrode 24 is small, an effect of dumping voltage fluctuation is small; and, when the resistance is small, charging to the capacitor is slow and thus the effect of suppressing voltage fluctuation is small. Therefore, an optimum value exists in the resistance value of the dummy gate electrode 24.

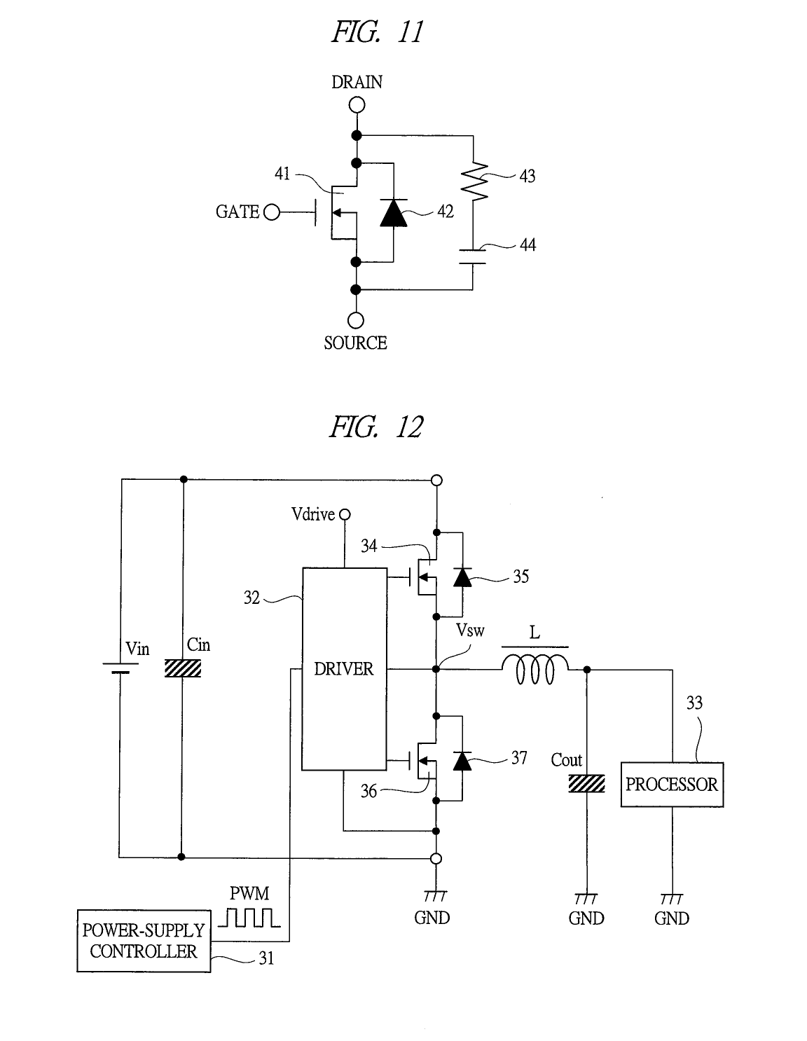

FIG. 12 illustrates a circuit configuration used in a power supply device which supplies power to a processor etc., and that is called non-isolated Buck converter. The non-isolated Buck converter includes an input power source Vin, an input capacitor Cin, a high-side MOSFET 34, an embedded diode 35 of the high-side MOSFET 34, a low-side MOSFET 36, an embedded diode 37 of the low-side MOSFET 36, a driver 32 that drives the high-side MOSFET 34 and the low-side MOSFET 36, a power source Vdrive of the driver 32, a power-supply controller 31 that supplies PWM signals to the driver 32, an output inductor L forming an output filter, an output capacitor Cout, and a processor 33 to be load.

In this non-isolated Buck converter, the high-side MOSFET 34 that is a first switching device and the low-side MOSFET 36 that is a second switching device are connected between a voltage input terminal connected to the input power source Vin and a reference potential terminal in series. Turning on and off of the high-side MOSFET 34 and the low-side MOSFET 36 are complementary controlled and current is flowed to the output inductor L that is an inductance device connected to connection nodes of the high-side MOSFET 34 and the low-side MOSFET 36, so that voltage obtained by converting voltage applied to the voltage input terminal is outputted.

When the high-side MOSFET 34 is turned on, drain voltage Vsw of the low-side MOSFET 36 is increased to the voltage of the input power source Vin. At this moment, the drain voltage Vsw of the low-side MOSFET 36 is increased to be larger than the input power source Vin due to influence of a parasitic inductance existing in the loop from the input capacitor Cin to the high-side MOSFET 34 and the low-side MOSFET 36, thereby generating voltage fluctuation. In recent years, since driving performance of the drive circuit is improved and switching of MOSFETs is performed at a high speed for reducing loss of the non-isolated Buck converter, influence of noise to electronic devices generated along with the voltage fluctuation has been problematic.

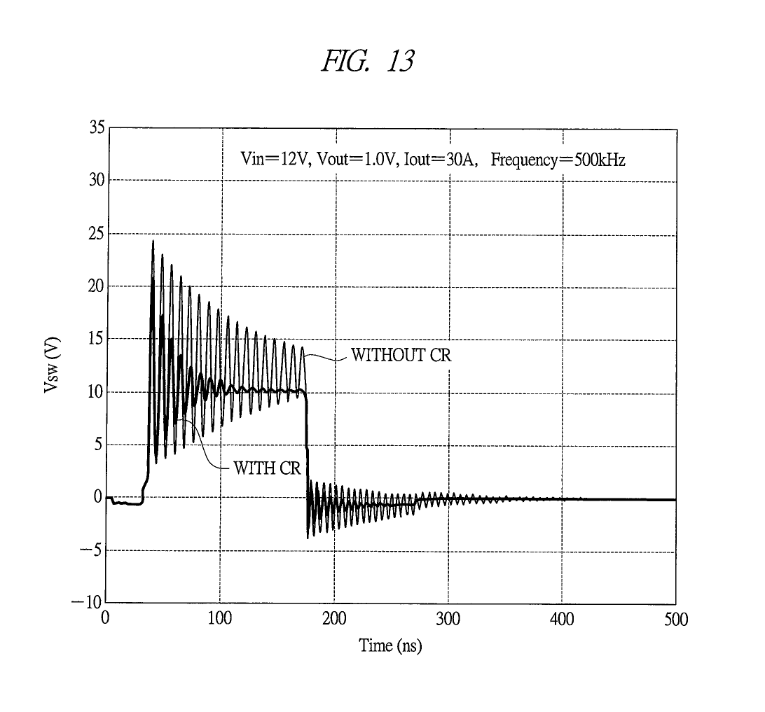

FIG. 13 illustrates a voltage waveform of the drain voltage Vsw of the low-side MOSFET upon turning on the high-side MOSFET 34. It can be observed that voltage fluctuation is suppressed when the snubber resistor 43 and the snubber capacitor 44 are present (the line indicated with “WITH CR” in FIG. 13) as compared to the situation where the snubber resistor 43 and the snubber capacitor 44 are not present (the line indicated with “WITHOUT CR”). This is because a voltage surge upon switching is mitigated by the snubber capacitor 44, so that the peak voltage is suppressed, and the snubber resistor 43 dumps the voltage fluctuation.

### Method of Manufacturing Semiconductor Device According to the Sixth Embodiment

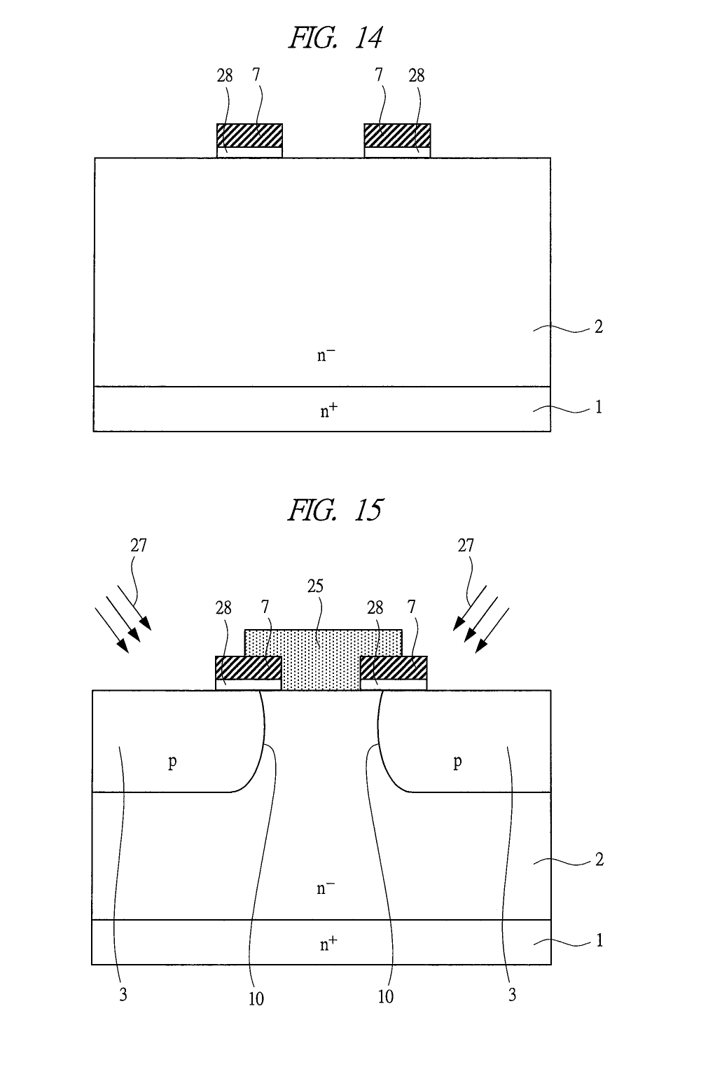

Next, with reference to FIGS. 14 to 19, a method of manufacturing the hollow gate type planar MOSFET according to the sixth embodiment will be described.

FIG. 14 is a cross-sectional view of the hollow gate type planar MOSFET after processing the gate insulator 28 and the gate electrode 7. FIG. 14 illustrates a state after finishing a step of forming a conductive film on a main surface of the n⁻-type layer 2 that is a drain region (semiconductor region having a first conductivity) interposing the gate insulator 28, and a step of performing patterning on the conductive film to form the gate electrode 7 on a first region on the main surface of the n⁻-type layer 2 with forming the gate opening to the gate electrode 7.

In the subsequent FIG. 15, the p-type well regions 3 are formed by self alignment in ion injection 27 in oblique directions after applying and patterning a photoresist 25 between the gate electrodes 7. By performing the ion injection 27 in oblique directions, the protruding portions 10 in the horizontal direction of the p-type wells 3 are formed to be positioned further inside than the substrate surface. FIG. 15 illustrates a state after finishing a step of forming the p-type well regions 3 which are channel forming regions (semiconductor regions having a second conductivity) by the ion injection 27 inclined to the vertical direction of the main surface of the n⁻-type layer 2 using an impurity of the second conductivity introduced in a second region of the main surface of the n⁻-type layer 2 by self alignment to the gate electrodes 7.

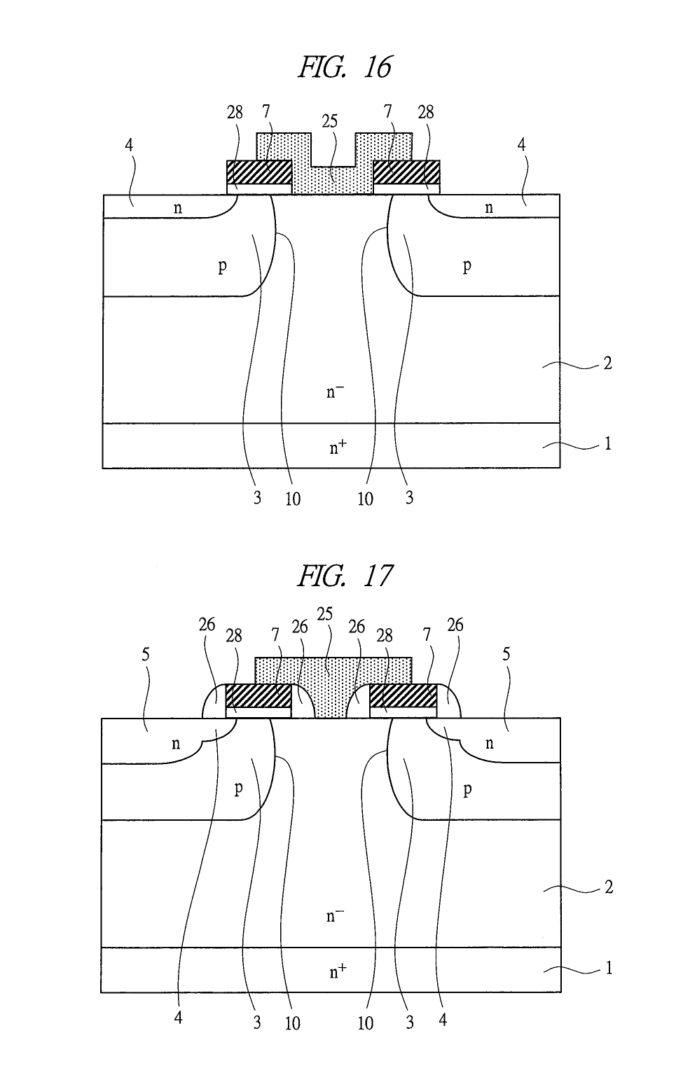

As illustrated in the subsequent FIG. 16, the shallow n-type source regions 4 are formed by self alignment in ion injection. FIG. 16 illustrates a state after finishing a step of forming the shallow n-type source regions 4 which are first source regions (semiconductor regions having the first conductivity) using an impurity of the first conductivity introduced by self alignment to the gate electrode 7 on the main surface of the p-type well regions 3.

As illustrated in the subsequent FIG. 17, after forming sidewalls 26 formed of an insulating film, the deep source regions 5 are formed by self alignment in ion injection. FIG. 17 illustrates a state after finishing a step of providing the sidewalls 26 formed of an insulating film to side surfaces of the gate electrode 7 and forming the deep source regions 5 which are second source regions (semiconductor regions having the first conductivity) having a larger depth than the shallow n-type source regions 4 using an impurity of the first conductivity introduced by self alignment to the gate electrodes 7 on the main surface of the p-type well regions 3.

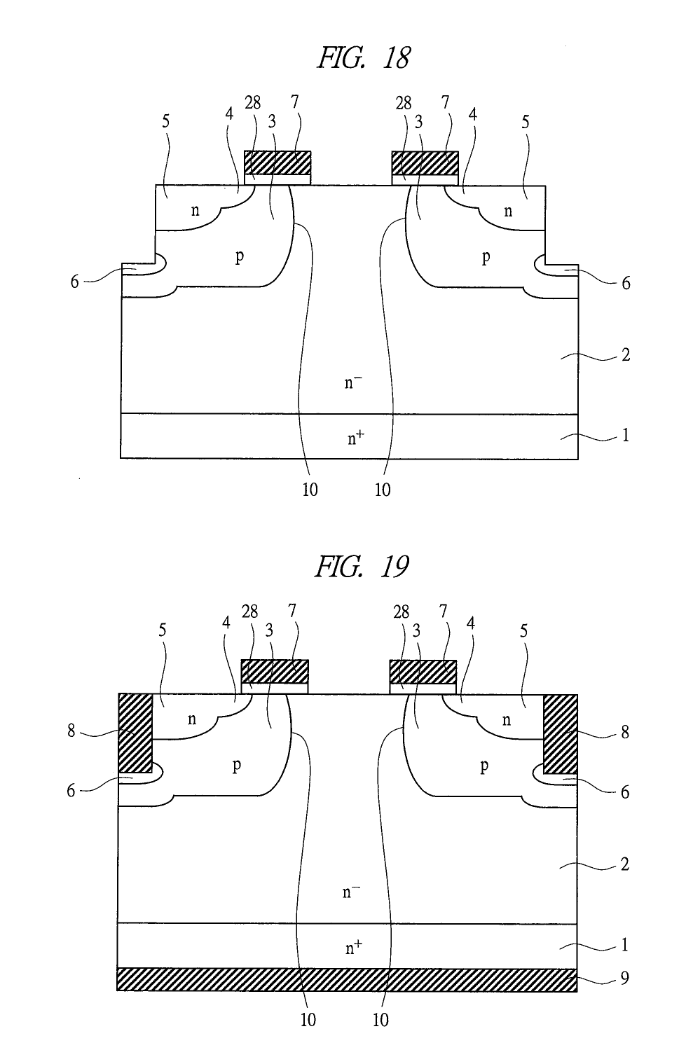

As illustrated in the subsequent FIG. 18, to connect the p-type well regions 3 and the source electrodes, trenches reaching the p-type wells 3 from the deep n-type source regions 5 are formed, and the p⁺-type contact regions 6 are formed by ion injection to reduce the contact resistance between the source electrodes and the p-type well regions 3.

As illustrated in the subsequent FIG. 19, after aluminum of the source electrodes 8 is vapor-deposited and processed, aluminum of the drain electrode 9 is vapor-deposited to a back surface.

In the above-described manner, the hollow gate type planar MOSFET according to the sixth embodiment can be manufactured. Note that, the planar MOSFET and the hollow gate type planar MOSFET according to other embodiments than the sixth embodiment can be manufactured in the same manner.

In the foregoing, the invention made by the inventors of the present invention has been concretely described based on the embodiments. However, it is needless to say that the present invention is not limited to the foregoing embodiments and various modifications and alterations can be made within the scope of the present invention.

The semiconductor device for power conversion according to the present invention can be particularly used in a power MOSFET and a power supply device using the power MOSFET.

What is claimed is:

1. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein, among the source regions, source regions in contact with the gate insulators have a shallow depth, and source regions away from the gate insulators have a large depth.

2. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein protruding portions in a horizontal direction of the well regions are positioned further inside than a surface of a substrate.

3. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein, among the source regions, source regions in contact with the gate insulators have a shallow depth, and source regions away from the gate insulators have a large depth, and
wherein protruding portions in a horizontal direction of the well regions are positioned further inside than a surface of a substrate.

4. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion, and
wherein, among the source regions, source regions in contact with the gate insulators have a shallow depth, and source regions away from the gate insulators have a large depth.

5. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion, and
wherein protruding portions in a horizontal direction of the well regions are positioned further inside than a surface of a substrate.

6. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion,
wherein, among the source regions, source regions in contact with the gate insulators have a shallow depth, and source regions away from the gate insulators have a large depth, and
wherein protruding portions in a horizontal direction of the well regions are positioned further inside than a surface of a substrate.

7. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion,
wherein, among the source regions, source regions in contact with the gate insulators have a shallow depth, and source regions away from the gate insulators have a large depth,
wherein protruding portions in a horizontal direction of the well regions are positioned further inside than a surface of a substrate, and
wherein the gate electrodes are formed of a stacked film of polysilicon and silicide.

8. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion,
wherein, among the source regions, source regions in contact with the gate insulators have a shallow depth, and source regions away from the gate insulators have a large depth,
wherein protruding portions in a horizontal direction of the well regions are positioned further inside than a surface of a substrate, and
wherein a region having an conductivity opposite to that of the well regions and a impurity concentration higher than that of the first semiconductor region is provided between the well regions.

9. A semiconductor device comprising a semiconductor substrate, a drain electrode formed to a back surface of the semiconductor substrate, a plurality of well regions formed on a surface of the semiconductor substrate, a first semiconductor region having a conductivity opposite to that of the well regions, a plurality of source regions formed in the well regions, gate insulators formed on the well regions and the first semiconductor region, and source electrodes electrically connected to the source regions,
wherein the gate electrode formed just above the first semiconductor region has an opening portion,
wherein, among the source regions, source regions in contact with the gate insulators have a shallow depth, and source regions away from the gate insulators have a large depth,
wherein protruding portions in a horizontal direction of the well regions are positioned further inside than a surface of a substrate, and
wherein a second insulator separated from the gate electrode and formed just above the first semiconductor region and a second electrode formed on the second insulator are provided to the opening portion of the gate electrode, the second electrode being electrically connected to the source electrodes.

10. A method of manufacturing a semiconductor device comprising the steps of:
a) forming a conductive film to a main surface of a semiconductor region having a first conductivity which is a drain region interposing a gate insulator;
b) performing a patterning on the conductive film to form a gate electrode on a first region of the main surface of the semiconductor region having the first conductivity and forming a gate opening to the gate electrode;
c) forming semiconductor regions having a second conductivity which are channel-forming regions by ion injection at an angle to a vertical direction of the main surface of the semiconductor region of the first conductivity using an impurity having the second conductivity introduced by self alignment to the gate electrode in a second region of the main surface of the semiconductor region having the first conductivity;
d) forming semiconductor regions having the first conductivity which are first source regions using an impurity having the first conductivity introduced into main surfaces of the semiconductor regions having the second conductivity by self alignment to the gate electrode;
e) providing insulators to side surfaces of the gate electrode and forming semiconductor regions having the first conductivity which are second source regions deeper than the first source regions using an impurity of the first conductivity introduced by self alignment to the gate electrode in the main surfaces of the semiconductor regions having the second conductivity.

11. A power supply device applying electrical current to an inductance element by complementary controlling turning on and off of a first switching device and a second switching device connected between a voltage input terminal and a reference potential terminal in series, the inductance element being connected to connection nodes of the first and second switching devices, so that voltage obtained by converting voltage applied to the voltage input terminal is outputted,
wherein the semiconductor device according to claim 1 is used in the first switching device or the second switching device.
